(19) United States
(12) Patent Application Publication
(10) Pub. No.: US 2004/0224475 A1
(43) Pub. Date: Nov. 11, 2004

(54) Methods of manufacturing semiconductor devices having a ruthenium layer via atomic layer deposition and associated apparatus and devices

(76) Inventors: Kwang-hee Lee, Seoul (KR); Cha-young Yoo, Gyeonggi-do (KR); Han-jin Lim, Seoul (KR); Jin-il Lee, Gyeonggi-do (KR); Suk-jin Chung, Gyeonggi-do (KR)

Correspondence Address: MYERS BIGEL SIBLEY & SAJOVEC, PO BOX 37428, RALEIGH, NC, 27627, US

(21) Appl. No.: 10/801,208

(22) Filed: Mar. 16, 2004

(30) Foreign Application Priority Data
Mar. 27, 2003 (KR) 10-2003-19258

(51) Int. Cl. H01L 21/20; C30B 1/00

(52) U.S. Cl. 438/399; 438/396; 438/398

(57) ABSTRACT

Methods of fabricating a semiconductor device are provided in which a storage node contact plug is formed on a semiconductor substrate. A ruthenium seed layer is then formed via atomic layer deposition on the storage node contact plug, and a main ruthenium layer is formed on the ruthenium seed layer. The main ruthenium layer and the ruthenium seed layer are patterned to form a lower electrode, and a dielectric layer is formed on the lower electrode. Finally, an upper electrode is formed on the dielectric layer. The upper electrode may be formed by forming a second ruthenium seed layer using atomic layer deposition on the dielectric layer and forming a second main ruthenium layer on the second ruthenium seed layer. The main ruthenium layer and/or the second main ruthenium layer may be formed via chemical vapor deposition.

### CROSS REFERENCE TO RELATED APPLICATION

This application claims the priority under 35 U.S.C. § 119 to Korean Patent Application No. 2003-19258, filed on Mar. 27, 2003 in the Korean Intellectual Property Office, the disclosure of which is incorporated herein in its entirety by reference.

### FIELD OF THE INVENTION

The present invention relates to methods of manufacturing semiconductor devices and, more particularly, to methods of manufacturing semiconductor devices having a ruthenium layer and apparatus that may be used in manufacturing such devices.

### BACKGROUND OF THE INVENTION

Ruthenium and various ruthenium compounds may exhibit excellent electrical properties such as, for example, very low resistivity. As such, ruthenium and compounds thereof have been used in recent years to form thin-film electrodes for various semiconductor devices including DRAMs, FERAMs and the like. The ruthenium and/or ruthenium compound layers that are used to form such thin-film electrodes may be deposited on a semiconductor substrate using, for example, sputtering or chemical vapor deposition (CVD) techniques. The CVD method has been widely employed to manufacture highly integrated semiconductor devices since it can facilitate the formation of a thin layer with a uniform thickness.

Conventionally, Ru(EtCp)₂ or Ru(OD)₃ has been used as the ruthenium source when forming a ruthenium layer using CVD techniques. Typically, a thin ruthenium layer having a uniform thickness may be formed when Ru(EtCp)₂ is used as the ruthenium source and the ruthenium is deposited on a planar surface on a semiconductor substrate. However, when the deposition surface is a non-planar surface having a high aspect ratio and/or a low critical dimension, it can be difficult to form a ruthenium or ruthenium compound layer using Ru(EtCp)₂ as the ruthenium source. This difficulty may arise because it can be difficult to properly supply the Ru(EtCp)₂ source in narrow spaces, which makes it difficult to form a ruthenium seed layer.

To improve the mobility of the Ru(EtCp)₂ source, a ruthenium seed layer may be grown by further supplying a large amount of oxygen (e.g., 1250 sccm) under a high pressure (e.g., 30 mTorr). Once the ruthenium seed layer is formed, the pressure may be lowered (e.g., to 0.5 Torr) and the oxygen flow rate may be reduced (e.g., to 45 sccm) and the main ruthenium layer may be formed. However, with this technique, a large amount of oxygen is supplied during the deposition of the ruthenium seed layer. As a result, the ruthenium layer tends to have a high concentration of oxygen. During thermal processing steps applied to the semiconductor device after deposition of the ruthenium layer, the oxygen atoms in the ruthenium layer may diffuse into, and thereby oxidize, a storage node contact plug or other layers of the semiconductor device. Such oxidation of the storage node contact plug may act to increase the contact resistance of the plug.

FIG. 1 is a graph depicting the composition of a semiconductor capacitor having a ruthenium upper electrode that was formed using conventional ruthenium deposition techniques according to XPS (X-ray photoelectron spectroscopy) analysis. In FIG. 1 (and in FIG. 4), the identifiers 3d, 1s, 2p and 4f reflect the electron state by orbital function. The ruthenium layer comprising the upper electrode was bombarded with photoelectrons by applying X-ray and then atoms contained in the ruthenium layer are sputtered from the ruthenium layer. The graph of FIG. 1 was obtained by analyzing the chemical composition of the atoms sputtered by photoelectron bombardment. As shown in FIG. 1, during the first three minutes of photoelectron bombardment the ruthenium elements and a large amount of oxygen was sputtered and released. As a result, the ruthenium layer that comprises the upper electrode contains a large amount of oxygen. This oxygen may diffuse into contact plugs and/or other layers that are disposed, for example, under the capacitor during subsequent thermal treatments. This same effect may also occur when Ru(OD)₃ is used as a ruthenium source, as Ru(OD)₃ intrinsically contains a large amount of oxygen that may oxidize the storage node contact plug or other layers either during the deposition of the ruthenium layer and/or during subsequent thermal processing steps.

### SUMMARY OF THE INVENTION

Pursuant to embodiments of the present invention, methods of fabricating a semiconductor device are provided in which a storage node contact plug is formed on a semiconductor substrate. A ruthenium seed layer is then formed via atomic layer deposition on the storage node contact plug, and a main ruthenium layer is formed on the ruthenium seed layer. The main ruthenium layer and the ruthenium seed layer are patterned to form a lower electrode, and a dielectric layer is formed on the lower electrode. Finally, an upper electrode is formed on the dielectric layer. The upper electrode may be formed by forming a second ruthenium seed layer using atomic layer deposition on the dielectric layer and forming a second main ruthenium layer on the second ruthenium seed layer. The main ruthenium layer and/or the second main ruthenium layer may be formed via chemical vapor deposition.

In certain embodiments of the present invention, the ruthenium seed layer is formed by injecting a ruthenium source into a chamber containing the semiconductor substrate, injecting an O₂-containing gas into the chamber, and then injecting an H₂-containing gas into the chamber. In these methods, the chamber may be purged following the injection of the ruthenium source, the O₂-containing gas, and/or the H₂-containing gas. The O₂-containing gas may, for example, be an O₂ gas, an O₃ gas, and/or an H₂O gas and the H₂-containing gas may be, for example, an H₂ gas and/or an NH₃ gas. Moreover, at least one of the O₂-containing gas or the H₂-containing gas may be supplied in a plasma phase. The sequence of injecting the ruthenium source, the O₂-containing gas, and the H₂-containing gas into the chamber may also be performed two or more time until the ruthenium seed layer is grown to a desired thickness.

In certain embodiments of the present invention, the ruthenium seed layer may be formed to a thickness of about 5 Å to 50 Å and the main ruthenium layer may be formed to a thickness of 50 Å to 300 Å. In forming the main ruthenium layer, oxygen may be supplied at a flow rate of about 1 sccm to 50 sccm and the ruthenium source may be supplied at a flow rate of about 0.1 ccm to 2 ccm. Both the oxygen source and the ruthenium source may be supplied under a pressure of about 0.4 Torr to 0.6 Torr. The ruthenium seed layer may have an oxygen concentration of less than 5%.

Pursuant to further embodiments of the present invention, methods of forming a ruthenium layer in a semiconductor device are provided in which atomic layer deposition is used to form a ruthenium seed layer on a semiconductor substrate. A gas containing hydrogen is then used to at least partially remove oxygen from the ruthenium seed layer. Then, a main ruthenium layer is formed on the ruthenium seed layer. The ruthenium seed layer may be formed on a non-planar surface that includes a recess having a height that is greater than a width of the recess and or that has substantially vertical sidewalls. The ruthenium seed layer may have a substantially uniform thickness.

In forming the ruthenium seed layer using atomic layer deposition a ruthenium source may be introduced into a chamber containing a semiconductor substrate. The chamber may then be purged and then an oxygen-containing gas may be introduced into the chamber, and subsequently the chamber may again be purged. In such embodiments, the oxygen-containing gas and/or the gas containing hydrogen may be supplied in a plasma phase.

The ruthenium seed layer may be formed on a contact layer such as, for example, a storage node contact plug. The main ruthenium layer may be deposited using chemical vapor deposition techniques, and the ruthenium seed layer may be a non-planar layer having a substantially uniform thickness.

Pursuant to still further embodiments of the present invention, methods of manufacturing a semiconductor memory device are provided in which an interlayer dielectric and a storage node contact plug are formed on a semiconductor substrate. A first ruthenium seed layer is formed via atomic layer deposition on the storage node contact plug, and a first main ruthenium layer is formed using chemical vapor deposition on the first ruthenium seed layer. A lower electrode is formed by polishing the first main ruthenium layer and the first ruthenium seed layer using, for example, chemical mechanical polishing, and a dielectric layer is formed on the lower electrode. A second ruthenium seed layer is formed via atomic layer deposition on the dielectric layer and an upper electrode is formed by forming a second main ruthenium layer using chemical vapor deposition on the second ruthenium seed layer.

Pursuant to still further embodiments of the present invention, semiconductor devices are provided that have a capacitor which includes a lower electrode on a semiconductor substrate, a dielectric layer (e.g., a tantalum oxide layer) on the lower electrode, and an upper electrode on the dielectric layer. The lower electrode may comprise a ruthenium seed layer having an oxygen content of less than 5% and a main ruthenium layer on the ruthenium seed layer. The upper electrode may comprise a second ruthenium seed layer having an oxygen content of less than 5% and a second main ruthenium layer on the ruthenium seed layer. In these devices, the ruthenium seed layer may have a thickness of about 5 Å to 50 Å and the main ruthenium layer may have a thickness of at least 50 Å. The ruthenium seed layer may have a substantially uniform thickness and an upper surface that is formed in a recess that has substantially vertical sidewalls.

Finally, apparatus for manufacturing a ruthenium layer on a semiconductor substrate, are also provided. These apparatus include an atomic layer deposition chamber that is configured to deposit a ruthenium seed layer on the semiconductor substrate via atomic level deposition and a chemical vapor deposition chamber that is configured to deposit a main ruthenium layer on the ruthenium seed layer via chemical vapor deposition. The apparatus also includes a transfer module that is operatively connected to the atomic layer deposition chamber and the chemical vapor deposition chamber. The transfer module is configured to transfer the semiconductor substrate between the atomic level deposition chamber and the chemical vapor deposition chamber.

### BRIEF DESCRIPTION OF THE DRAWING

The features and advantages of the present invention will become more apparent by the following description of exemplary embodiments thereof with reference to the attached drawings in which:

FIG. 1 is a graph depicting the composition of a conventional semiconductor capacitor having a ruthenium upper electrode;

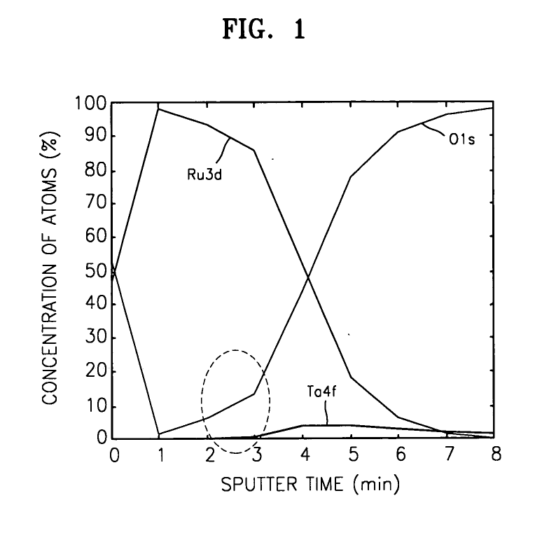

FIGS. 2A through 2D are cross-sectional views of a semiconductor device illustrating operations for manufacturing a semiconductor memory device having a ruthenium layer according to certain embodiments of the present invention;

FIG. 3 shows an apparatus for manufacturing a ruthenium layer according to certain embodiments of the present invention; and

FIG. 4 is a graph showing the composition of a semiconductor capacitor according to certain embodiments of the present invention.

### DETAILED DESCRIPTION

The present invention will now be described more fully with reference to the accompanying drawings, in which exemplary embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions may be exaggerated for clarity. It will also be understood that when a layer or element is referred to as being “on” another layer, element or substrate, it can be directly on the other layer, element or substrate, or intervening layers and/or elements may also be present. In contrast, when a layer/element is referred to as being “directly on” another layer/element/substrate, there are no intervening layers or elements present. Like reference numerals refer to like elements throughout.

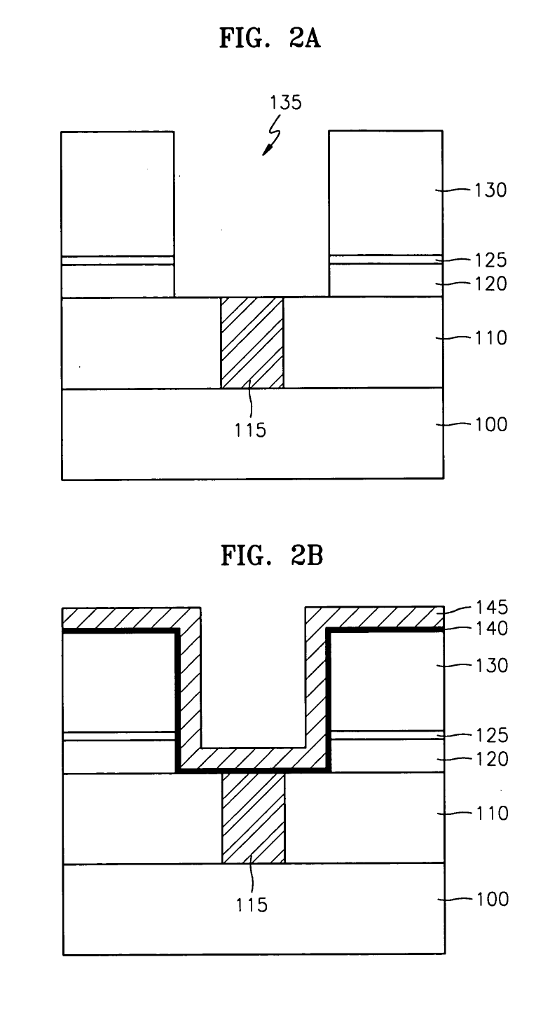

FIGS. 2A-2D illustrate operations for fabricating microelectronic devices such as a capacitor having ruthenium electrodes according to certain embodiments of the present invention. As shown in FIG. 2A, a first interlayer dielectric (ILD) 110 is formed on a semiconductor substrate 100. A MOS transistor including a gate, a source, and a drain, as well as a bit line that is electrically connected to the drain, may also be formed on the semiconductor substrate 100 (neither the MOS transistor nor the bit line are pictured in FIGS. 2A-2D). A storage node contact plug 115 may be formed, using known methods, in the first ILD 110 so as to be electrically connected to the source of the MOS transistor. The storage node contact plug 115 may be formed, for example, of titanium nitride (TiN). A second ILD 120, an etch stopper 125, and a third ILD 130 may be sequentially formed on the first ILD 110 and the storage node contact plug 115, thereby forming a sacrificial oxide layer. The second ILD 120 and the third ILD 130 may be formed of silicon oxide such as, for example, a plasma-TEOS layer, while the etch stopper 125 may be formed, for example, as a silicon nitride layer (which has a high etch selectivity with respect to silicon oxide). The second ILD 120, the etch stopper 125, and the third ILD 130 may determine the height of the lower electrode of the capacitor. As is also shown in FIG. 2A, predetermined portions of the third ILD 130, the etch stopper 125, and the second ILD 120 may be removed by, for example, etching, until the storage node contact plug 115 is exposed. The exposed area defines a lower electrode region 135.

As shown in FIG. 2B, a ruthenium seed layer 140 may be formed in the lower electrode region 135 and on the third ILD 130. The ruthenium seed layer 140 may be formed using atomic layer deposition (ALD) to a thickness of about 5 Å to 50 Å. The formation of the ruthenium seed layer 140 using ALD may comprise, for example, (a) injecting a ruthenium source into a chamber containing the semiconductor substrate, (b) purging the chamber and the surface of the resultant structure, (c) injecting an O₂-containing gas into the chamber, (d) purging the chamber and the surface of the resultant structure, (e) injecting an H₂-containing gas into the chamber, and (f) purging the chamber and the surface of the resultant structure. The supply of the H₂-containing gas may facilitate the removal of impurities including, for example, oxygen, from the ruthenium seed layer 140. The steps (a) through (f) may be repeated until the desired thickness of the ruthenium seed layer 140 is obtained.

The ruthenium source may be, for example, an Ru(EtCp)₂ source. The O₂-containing gas may be, for example, an O₂ gas, an O₃ gas, and/or an H₂O gas. The H₂-containing gas may be, for example, an H₂ gas and/or an NH₃ gas. The deposition of the ruthenium seed layer 140 may be more efficient if the O₂-containing gas and/or the H₂-containing gas are supplied in a plasma phase. By forming the ruthenium seed layer 140 using ALD it generally may be possible to form layers having a uniform thickness on narrow, non-planar regions without introducing a large amount of oxygen during the formation of the ruthenium seed layer.

As is also shown in FIG. 2B, a main ruthenium layer 145 may be deposited on the ruthenium seed layer 140. The main ruthenium layer 145 can be formed using, for example, CVD. The deposition rate of the CVD process typically will be higher than the deposition rate of the ALD process used to form the ruthenium seed layer 140. By way of example, the main ruthenium layer 145 can be formed by supplying oxygen and a ruthenium source at a flow rate of 1 sccm to 50 sccm and 0.1 ccm to 2 ccm, respectively, under a pressure of about 0.4 Torr to 0.6 Torr. In certain embodiments of the present invention, the main ruthenium layer 145 may be deposited to a thickness of about 50 Å to 300 Å. Since the main ruthenium layer 145 is deposited on the ruthenium seed layer 140, it generally is possible to grow a main ruthenium layer 145 even in narrow, non-planar areas with relatively low oxygen flow rates.

Next, a sacrificial layer may be deposited on the main ruthenium layer 145. As shown in FIG. 2C, the sacrificial layer (not shown in FIG. 2C), the main ruthenium layer 145, and the ruthenium seed layer 140 may be removed using, for example, chemical mechanical polishing (CMP) until the surface of the third ILD 130 is exposed, thereby forming a concave lower electrode 150.

As shown in FIG. 2D, a dielectric layer 155 may be deposited on the lower electrode 150 and the third ILD 130. An upper electrode 170 is then formed on the dielectric layer 155. The dielectric layer 155 may be, for example, a TaO layer, and the upper electrode 170 may be, for example, an Ru layer. Like the lower electrode 150, the upper electrode 170 may be fabricated by forming a ruthenium seed layer 160 using ALD and then forming a main ruthenium layer 165 on the ruthenium seed layer 160 using CVD.

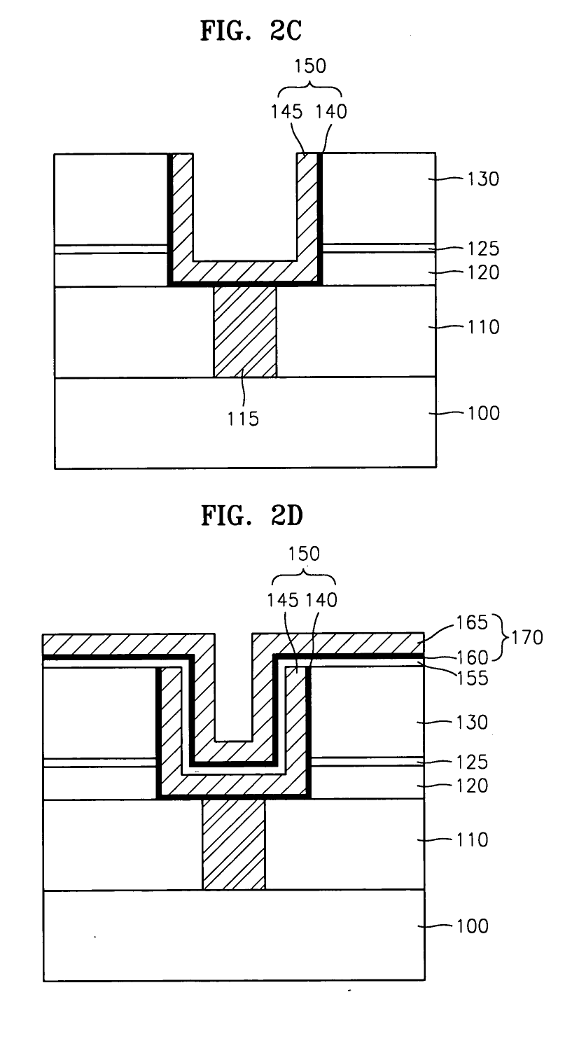

Pursuant to further embodiments of the present invention, an integrated apparatus 200 that includes both an ALD chamber and a CVD chamber may be used to form the ruthenium seed layer 140 and the main ruthenium layer 145. As shown in FIG. 3, an apparatus 200 for manufacturing a ruthenium layer may comprise a transfer module 210 which loads a wafer, an ALD chamber 220 which may be disposed on one side of the transfer module 210, and a CVD chamber 230 which may be disposed on the other side of the transfer module 210. In this apparatus 200 for manufacturing a ruthenium layer, since the ALD chamber 220 and the CVD chamber 230 are connected to each other by the transfer module 210, the ruthenium seed layer 140 and the main ruthenium layer 145 can be deposited without breaking vacuum.

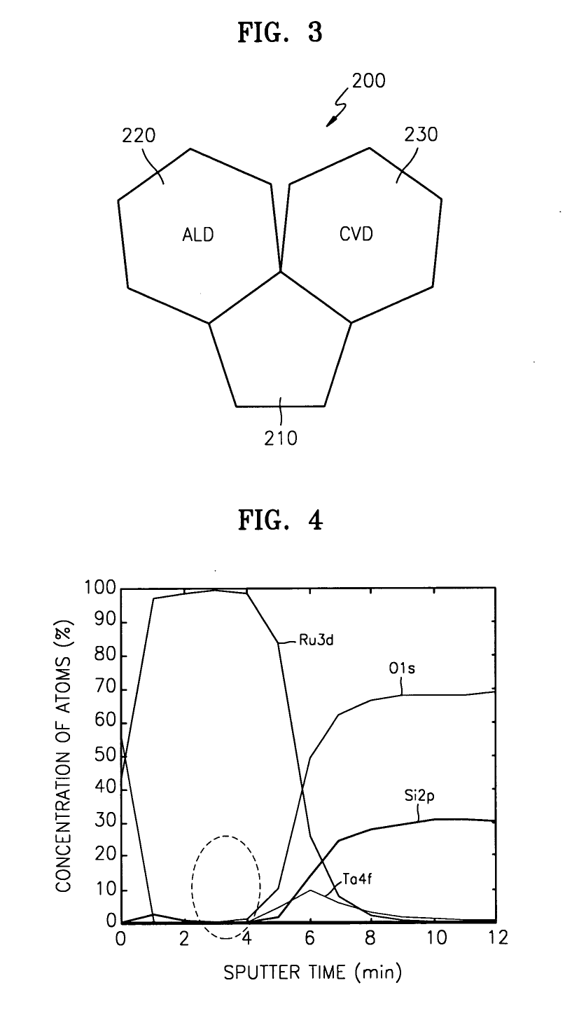

FIG. 4 is a graph obtained by analyzing the chemical composition of a semiconductor capacitor constructed according to certain embodiments of the present invention according to XPS (X-ray photoelectron spectroscopy). As shown in FIG. 4, during the first four minutes, only ruthenium elements were released. Thereafter, by the XPS analysis tantalum elements and oxygen elements also were released. Thus, the ruthenium layer exhibits a low concentration of oxygen (less than 5%), which may serve to minimize and/or prevent diffusion of oxygen from the ruthenium layer to other layers (such as the storage node contact plug 115) during subsequent thermal treatments of the device.

Thus, pursuant to certain embodiments of the present invention, a ruthenium layer may be fabricated by forming a ruthenium seed layer using ALD and then forming a main ruthenium layer using other deposition techniques such as, for example, CVD. The ALD process may be used to form a thin, uniform ruthenium seed layer on non-planar surfaces having high aspect ratios without having to supply a large amount of oxygen under high pressure. Since the main ruthenium layer may be formed using conventional techniques such as, for example, CVD, a ruthenium layer having a certain thickness can be deposited at a high speed. Thus, pursuant to some embodiments of the present invention a low oxygen content ruthenium layer may be formed on a high aspect ratio non-planar surface at relatively high speeds. As such, diffusion of oxygen from the ruthenium layer into, for example, a storage node contact plug or other electrical contact can be reduced or minimized, as can the degradation in contact resistance that can result from such exposure of the contact to oxygen.

While the present invention has been described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating an electrode for a microelectronic device, the method comprising:
forming a ruthenium seed layer using atomic layer deposition on a semiconductor substrate;
forming a main ruthenium layer on the ruthenium seed layer; and
patterning the main ruthenium layer and the ruthenium seed layer to form the electrode.

2. The method of claim 1, further comprising:
forming a dielectric layer on the electrode; and
forming an upper electrode on the dielectric layer to provide a capacitor.

3. The method of claim 2, further comprising forming a storage node contact plug on the semiconductor substrate and a storage node that is electrically connected to the storage node contact plug to provide a semiconductor memory device, wherein the ruthenium seed layer is formed on the storage node contact plug.

4. The method of claim 1, wherein forming the ruthenium seed layer using atomic layer deposition comprises:
injecting a ruthenium source into a chamber containing the semiconductor substrate; then
injecting an O₂-containing gas into the chamber containing the semiconductor substrate; and then
injecting an H₂-containing gas into the chamber containing the semiconductor substrate.

5. The method of claim 4, further comprising purging the chamber following the injection of the ruthenium source, the injection of the O₂-containing gas, and the injection of the H₂-containing gas.

6. The method of claim 4, wherein the O₂-containing gas comprises an O₂ gas, an O₃ gas, and/or an H₂O gas and the H₂-containing gas comprises an H₂ gas and/or an NH₃ gas.

7. The method of claim 4, wherein at least one of the O₂-containing gas or the H₂-containing gas is supplied in a plasma phase.

8. The method of claim 4, wherein injecting the ruthenium source, injecting the O₂-containing gas, and injecting the H₂-containing gas into the chamber is performed at least twice until the ruthenium seed layer is grown to a desired thickness.

9. The method of claim 1, wherein the ruthenium seed layer is formed to a thickness of about 5 Å to 50 Å and wherein the main ruthenium layer is formed to a thickness of 50 Å to 300 Å.

10. The method of claim 1, wherein the forming of the main ruthenium layer comprises supplying oxygen at a flow rate of about 1 sccm to 50 sccm and supplying a ruthenium source at a flow rate of about 0.1 ccm to 2 ccm under a pressure of about 0.4 Torr to 0.6 Torr.

11. The method of claim 2, wherein the dielectric layer comprises a tantalum oxide layer.

12. The method of claim 2, wherein the forming of the upper electrode comprises:
forming a second ruthenium seed layer using atomic layer deposition on the dielectric layer; and
forming a second main ruthenium layer on the second ruthenium seed layer.

13. The method of claim 1, wherein the main ruthenium layer is formed using chemical vapor deposition.

14. The method of claim 1, wherein the ruthenium seed layer has an oxygen concentration of less than 5%.

15. A method of forming a ruthenium layer in a semiconductor device, the method comprising:
using atomic layer deposition to form a ruthenium seed layer on a semiconductor substrate;
using a gas containing hydrogen to remove impurities from the ruthenium seed layer; and
forming a main ruthenium layer on the ruthenium seed layer.

16. The method of claim 15, wherein the ruthenium seed layer is formed on a non-planar surface.

17. The method of claim 16, wherein the non-planar surface includes a recess having a height that is greater than a width of the recess.

18. The method of claim 16, wherein the non-planar surface includes a recess having substantially vertical sidewalls.

19. The method of claim 16, wherein the ruthenium seed layer has a substantially uniform thickness.

20. The method of claim 15, wherein using atomic layer deposition to form a ruthenium seed layer on a semiconductor substrate comprises:
introducing a ruthenium source into a chamber containing the semiconductor substrate;
purging the chamber; and then
introducing an oxygen-containing gas into the chamber; and
purging the chamber.

21. The method of claim 20, wherein the oxygen-containing gas and the gas containing hydrogen are supplied in a plasma phase.

22. The method of claim 15, wherein the ruthenium seed layer is formed on a contact layer.

23. The method of claim 15, wherein the main ruthenium layer is deposited using chemical vapor deposition techniques and wherein the ruthenium seed layer is a non-planar layer having a substantially uniform thickness.

24. The method of claim 15, wherein the ruthenium seed layer is formed to a thickness of about 5 Å to 50 Å and wherein the main ruthenium layer is formed to a thickness of 50 Å to 300 Å.

25. A method of manufacturing a semiconductor memory device, the method comprising:
forming an interlayer dielectric and a storage node contact plug on a semiconductor substrate;
forming a first ruthenium seed layer using atomic layer deposition on the storage node contact plug;
forming a first main ruthenium layer using chemical vapor deposition on the first ruthenium seed layer;
forming a lower electrode by polishing the first main ruthenium layer and the first ruthenium seed layer using chemical mechanical polishing;
forming a dielectric layer on the lower electrode;
forming a second ruthenium seed layer using atomic layer deposition on the dielectric layer; and
completing an upper electrode by forming a second main ruthenium layer using chemical vapor deposition on the second ruthenium seed layer.

26. The method of claim 25, further comprising:
forming a sacrificial oxide layer on the interlayer dielectric and the storage node contact plug;
forming a lower electrode region by etching the sacrificial oxide layer until the storage node contact plug is exposed; and
wherein the first ruthenium seed layer is formed on the lower electrode region and the sacrificial oxide layer.

27. A semiconductor device having a capacitor, comprising:
a lower electrode on a semiconductor substrate, the lower electrode comprising a first ruthenium seed layer having an oxygen content of less than 5% and a first main ruthenium layer on the first ruthenium seed layer;
a dielectric layer on the lower electrode; and
an upper electrode comprising a second ruthenium seed layer having an oxygen content of less than 5% and a second main ruthenium layer on the ruthenium seed layer.

28. The semiconductor device of claim 27, wherein the first ruthenium seed layer has a thickness of about 5 Å to 50 Å and the first main ruthenium layer has a thickness of at least 50 Å.

29. The semiconductor device of claim 28, wherein the dielectric layer comprises a tantalum oxide layer.

30. The semiconductor device of claim 27, wherein the first ruthenium seed layer has a substantially uniform thickness and an upper surface of the first ruthenium seed layer is non-planar.

31. The semiconductor device of claim 27, wherein the first ruthenium seed layer is formed in a recess that has substantially vertical sidewalls.

32. An apparatus for manufacturing a ruthenium layer on a semiconductor substrate, the apparatus comprising:
an atomic layer deposition chamber that is configured to deposit a ruthenium seed layer on the semiconductor substrate via atomic level deposition;
a chemical vapor deposition chamber that is configured to deposit a main ruthenium layer on the ruthenium seed layer via chemical vapor deposition; and
a transfer module operatively connected to the atomic layer deposition chamber and the chemical vapor deposition chamber that is configured to transfer the semiconductor substrate between the atomic level deposition chamber and the chemical vapor deposition chamber.

33. The apparatus of claim 32, wherein the transfer module is configured to transfer the semiconductor substrate between the atomic level deposition chamber and the chemical vapor deposition chamber without breaking vacuum.
